(19) United States
(12) Patent Application Publication
(10) Pub. No.: US 2021/0143197 A1
(43) Pub. Date: May 13, 2021

(54) IMAGE SENSING DEVICE

(71) Applicant: SK hynix Inc., Icheon-si (KR)

(72) Inventor: Woo Yung Jung, Seoul (KR)

(21) Appl. No.: 16/913,030

(22) Filed: Jun. 26, 2020

(30) Foreign Application Priority Data
Nov. 7, 2019 (KR) 10-2019-0141835

(51) Int. Cl. H01L 27/146

(52) U.S. Cl. CPC H01L 27/14623; H01L 27/14607

(57) ABSTRACT

An image sensing device is disclosed. The image sensing device includes a substrate, an array of unit pixels and a grid structure formed over the substrate and between adjacent unit pixels to prevent crosstalk between contiguous unit pixels. The grid structure includes a pixel grid region in which first light shielding patterns extending in a first direction and second light shielding patterns extending in a second direction perpendicular to the first direction are arranged to cross each other, and an open grid region coupled to the pixel grid region and including first light shielding patterns extending in the first direction and second light shielding patterns extending in the second direction, the first light shielding patterns and the second light shielding patterns arranged not to cross each other. The first light shielding patterns and the second light shielding patterns include an air layer and a capping layer disposed over the air layer. The open grid region includes an open region in which at least one of the first light shielding patterns or the second light shielding patterns is configured to include an air layer without the capping layer disposed over the air layer.

### CROSS-REFERENCE TO RELATED APPLICATION

This patent document claims the priority and benefits of Korean patent application No. 10-2019-0141835, filed on Nov. 7, 2019, which is incorporated by reference in its entirety as part of the disclosure of this patent document.

### TECHNICAL FIELD

The technology and implementations disclosed in this patent document generally relate to an image sensing device.

### BACKGROUND

An image sensor is a device for converting an optical image into electrical signals. With the recent development of computer industries and communication industries, demand for high-quality and high-performance image sensors is rapidly increasing in various fields, for example, digital cameras, camcorders, personal communication systems (PCSs), game consoles, surveillance cameras, medical micro-cameras, robots, etc.

### SUMMARY

The disclosed technology relates to an image sensing device.

In one aspect, an image sensing device is provided to comprise: a grid structure formed over a substrate, and configured to prevent crosstalk between contiguous unit pixels, wherein the grid structure includes: a pixel grid pattern in which first light shielding patterns proceeding in a first direction and second light shielding patterns proceeding in a second direction perpendicular to the first direction are arranged to cross each other in a lattice structure; and at least one open grid pattern coupled to the pixel grid pattern, and configured to have the first light shielding patterns and the second light shielding patterns not crossing the first light shielding patterns such that the first light shielding patterns and the second light shielding patterns are formed in a line shape, wherein the first light shielding patterns and the second light shielding patterns include: an air layer; and a capping film formed to cap the air layer, wherein the at least one open grid pattern includes: an open region in which the capping film is not formed in the first light shielding patterns or the second light shielding patterns.

In accordance with an implementation of the disclosed technology, an image sensing device is provided to include a substrate, an array of unit pixels each operable to receive light and to produce pixel signals representative of the received light and a grid structure formed over the substrate and between adjacent unit pixels to prevent crosstalk between contiguous unit pixels. The grid structure may include a pixel grid region in which first light shielding patterns extending in a first direction and second light shielding patterns extending in a second direction perpendicular to the first direction are arranged to cross each other, and an open grid region coupled to the pixel grid region and including first light shielding patterns extending in the first direction and second light shielding patterns extending in the second direction, the first light shielding patterns and the second light shielding patterns arranged not to cross each other. The first light shielding patterns and the second light shielding patterns in the pixel grid region may include an air layer and a capping layer disposed over the air layer. The open grid region may include an open region in which at least one of the first light shielding patterns or the second light shielding patterns is configured to include an air layer without the capping layer disposed over the air layer.

In another aspect, an image sensing device is provided to comprise: an active pixel region configured to include active pixels which detect light of a scene to produce pixel signals representing the detected scene including spatial information of the detected scene; a dummy pixel region including dummy pixels located at different locations from locations of the active pixels of the active pixel region, each dummy pixel structured to detect light; a first grid structure disposed in the active pixel region and a part of the dummy pixel region and including first light shielding patterns and second light shielding patterns that are arranged to cross each other and include an air layer and a capping layer disposed over the air layer; and a second gird structure disposed in another part of the dummy pixel region and including first light shielding patterns and second light shielding patterns that are arranged not to cross each other, wherein the second grid structure is configured to provide an open region in which at least one of the first light shielding patterns or the second light shielding patterns is configured to include an air layer without a capping layer disposed over the air layer.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some implementations of the disclosed technology.

FIG. 2 is a schematic diagram illustrating an air grid formed in a pixel region shown in FIG. 1 based on some implementations of the disclosed technology.

FIG. 3 is an enlarged view illustrating a partial region of an air grid formed in an effective pixel region and a dummy pixel region shown in FIG. 2 based on some implementations of the disclosed technology.

FIG. 4 is a cross-sectional view illustrating an air grid taken along the line A-A′ shown in FIG. 3 based on some implementations of the disclosed technology.

FIG. 5 is a cross-sectional view illustrating an air grid taken along the line B-B′ shown in FIG. 3 based on some implementations of the disclosed technology.

FIG. 6 is a schematic diagram illustrating a lattice-shaped air grid from which an end portion is removed based on some implementations of the disclosed technology.

FIGS. 7A to 7F are cross-sectional views illustrating a method for forming the structure shown in FIG. 4 based on some implementations of the disclosed technology.

FIG. 8 is a schematic diagram illustrating an air grid formed in the pixel region shown in FIG. 1 based on some implementations of the disclosed technology.

FIG. 9 is a horizontal cross-sectional view illustrating an example of an end portion of an open grid pattern shown in FIG. 8 based on some implementations of the disclosed technology.

FIG. 10 is a schematic diagram illustrating an air grid formed in a pixel region shown in FIG. 1 based on some implementations of the disclosed technology.

FIG. 11 is a schematic diagram illustrating an air grid formed in a pixel region shown in FIG. 1 based on some implementations of the disclosed technology.

### DETAILED DESCRIPTION

This patent document provides implementations and examples of an image sensing device that substantially addresses one or more issues due to limitations and disadvantages of the related art. Some implementations of the disclosed technology suggest designs of an image sensing device for preventing collapse of an air grid. In recognition of the issues above, the disclosed technology provides various implementations of an image sensing device which can prevent collapse or deformation of the air grid by preventing expansion of the air grid.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

FIG. 1 is a block diagram illustrating an example of an image sensing device based on some implementations of the disclosed technology.

Referring to FIG. 1, the image sensing device may include a pixel region 100, a correlated double sampler (CDS) 200, an analog-to-digital converter (ADC) 300, a buffer 400, a row driver 500, a timing generator 600, a control register 700, and a ramp signal generator 800.

The pixel region 100 may include unit pixels (PXs) consecutively arranged in a two-dimensional (2D) structure in which unit pixels are arranged in a first direction and a second direction perpendicular to the first direction. Each of the unit pixels (PXs) may convert incident light into an electrical signal to generate a pixel signal, and may output the pixel signal to the correlated double sampler (CDS) 200 through column lines. The unit pixels (PXs) may be coupled not only to one of row lines, but also to one of column lines. The pixel region 100 may include air grid (ARD) for preventing crosstalk between contiguous (or adjacent) unit pixels (PXs). The air grid (ARD) may include a structure in which an air layer is capped or covered by a capping film. In some implementations, the air grid (ARD) may include a collapse prevention structure that can maintain the shape of the capping film and minimize a risk of collapsing due to thermal expansion of air in a thermal annealing process. The collapse prevention structure has a portion in which the capping film is not formed. The collapse prevention structure will be described later in this document in more detail.

In some implementations, the image sensing device may use the correlated double sampler (CDS) to remove an offset value of pixels by sampling a pixel signal twice so that the difference is taken between these two samples. For example, the correlated double sampler (CDS) may remove an offset value of pixels by comparing pixel output voltages obtained before and after light is incident on the pixels, so that only pixel signals based on the incident light can be actually measured. The correlated double sampler (CDS) 200 may hold and sample electrical image signals received from the pixels (PXs) of the pixel region 100. For example, the correlated double sampler (CDS) 200 may perform sampling of a reference voltage level and a voltage level of the received electrical image signal in response to a clock signal received from the timing generator 600, and may transmit an analog signal corresponding to a difference between the reference voltage level and the voltage level of the received electrical image signal to the analog-to-digital converter (ADC) 300.

The analog-to-digital converter (ADC) 300 may compare a ramp signal received from the ramp signal generator 800 with a sampling signal received from the correlated double sampler (CDS) 200, and may thus output a comparison signal indicating the result of comparison between the ramp signal and the sampling signal. The analog-to-digital converter (ADC) 300 may count a level transition time of the comparison signal in response to a clock signal received from the timing generator 600, and may output a count value indicating the counted level transition time to the buffer 400.

The buffer 400 may store each of the digital signals received from the analog-to-digital converter (ADC) 300, may sense and amplify each of the digital signals, and may output each of the amplified digital signals. Therefore, the buffer 400 may include a memory (not shown) and a sense amplifier (not shown). The memory may store the count value, and the count value may be associated with output signals of the plurality of unit pixels (PXs). The sense amplifier may sense and amplify each count value received from the memory.

The row driver 500 may drive the pixel region 100 in units of a row line in response to an output signal of the timing generator 600. For example, the row driver 500 may generate a selection signal capable of selecting any one of the plurality of row lines.

The timing generator 600 may generate a timing signal to control the row driver 500, the correlated double sampler (CDS) 200, the analog-to-digital converter (ADC) 300, and the ramp signal generator 800.

The control register 700 may generate control signals to control the ramp signal generator 800, the timing generator 600, and the buffer 400.

The ramp signal generator 800 may generate a ramp signal to control an image signal output to the buffer 400 in response to a control signal received from the control register 700 and a timing signal received from the timing generator 600. The ramp signal can be compared with electrical signals (e.g., the sampling signal) generated by pixels.

FIG. 2 is a schematic diagram illustrating an air grid formed in the pixel region 100 shown in FIG. 1 based on some implementations of the disclosed technology.

Referring to FIG. 2, the pixel region 100 may include an effective pixel region 110 and a dummy pixel region 120. The effective pixel region 110 may be formed in a rectangular shape, and the rectangular effective pixel region 110 may be arranged at the center of the image sensing device. The dummy pixel region 120 may be arranged in a rectangular frame shape surrounding the effective pixel region 110.

The effective pixel region 110 may include a plurality of effective pixels 112, and the dummy pixel region 120 may include a plurality of dummy pixels 122. The effective pixels 112 in the effective pixel region 110 are used for image sensing and for representing the spatial and other imaging information of an input scene or image to be detected. The dummy pixels 122 in the dummy pixel region 120 separate dummy pixel region are different and are not used directly to provide spatial and other imaging information. Rather, the dummy pixels 122 are designed and operated to provide supplemental information in the imaging operation of the effective pixel region 110 to improve overall imaging operation of the image sensing device. The air grid (ARD) may be formed in the effective pixel region 110 and the dummy pixel region 120. The air grid (ARD) may be formed between any two adjacent color filters, and may thus prevent crosstalk between the contiguous unit pixels 112 and 122. The air grid (ARD) may include a structure in which the air layer is capped or covered by the capping film.

The air grid (ARD) may include a collapse prevention structure 124 to prevent the collapse of the capping film due to the expansion of air. The collapse prevention structure 124 may be formed in the dummy pixel region 120, and may be formed in a zigzag pattern.

FIG. 3 is an enlarged view illustrating a partial region of the air grid formed in the effective pixel region and the dummy pixel region shown in FIG. 2. FIG. 4 is a cross-sectional view illustrating the air grid taken along the line A-A′ shown in FIG. 3. FIG. 5 is a cross-sectional view illustrating the air grid taken along the line B-B′ shown in FIG. 3 based on some implementations of the disclosed technology.

Referring to FIGS. 3 to 5, the air grid (ARD) may be formed over a substrate 101, and may include a pixel grid pattern (PX_ARD) and an open grid pattern (OP1_ARD).

The pixel grid pattern (PX_ARD) may include a plurality of light shielding patterns 102 formed in a first direction, and a plurality of light shielding patterns 104 formed in a second direction perpendicular to the first direction. The pixel grid pattern (PX_ARD) according to the disclosed technology may include a lattice-shaped region in the air grid (ARD). In some implementations, the light shielding patterns 102 extending in the first direction and the light shielding patterns 104 extending in the second direction may cross each other to form a lattice shape.

The open grid pattern (OP1_ARD) may include a plurality of light shielding patterns 106 extending in the first direction and a plurality of light shielding patterns 108 extending in the second direction. The open grid pattern (OP1_ARD) may provide a line-shaped region in the air grid (ARD). In the line-shaped region, the light shielding patterns 106 extending in the first direction and the light shielding patterns 108 extending in the second direction may be formed in a line shape without crossing each other. For convenience of the description, hereinafter, the light shielding patterns 102 and 106 extending in the first direction will be referred to as first light shielding patterns, and the light shielding patterns 104 and 108 extending in the second direction will be referred to as second light shielding patterns.

Each of the first light shielding patterns 102 and 106 and each of the second light shielding patterns 104 and 108 may include a metal layer 131, an insulation layer 132, an air layer 133, a support film 134, and a capping film 135. Thus, the first light shielding patterns 102 and 106 and the second light shielding patterns 104 and 108 may be formed in a hybrid structure including the air layer 133 and the metal layer 131.

In some implementations, the metal layer 131 may include tungsten (W).

The insulation layer 132 may be formed to cap the metal layer 131 such that expansion of the metal layer 131 can be prevented or minimized in a thermal annealing process. The insulation layer 132 may include a silicon nitride film (SiₓN_{y}, where each of ‘x’ and ‘y’ is a natural number) or a silicon oxide nitride film (SiₓO_{y}N_{z}, where each of ‘x’, ‘y’, and ‘z’ is a natural number). The insulation layer 132 may be formed to extend to a region in which the color filters of the unit pixels 112 and 122 are formed. Thus, the insulation layer 132 may extend to a lower region of each color filter.

In some implementations, the first light shielding patterns 102 and 106 and the second light shielding patterns 104 and 108 may not include the insulation layer 132 and the metal layer 131.

The support film 134 may allow the shape of the air grid (ARD) to remain unchanged, and may prevent the capping film 135 from collapsing in a process for forming the air layer 133 in the air grid (ARD). The support film 134 may include an insulation layer that is different in etch selectivity from a carbon-containing Spin On Carbon (SOC) film. The support film 134 may include at least one of a silicon oxide nitride film (SiₓO_{y}N_{z}, where each of ‘x’, ‘y’, and ‘z’ is a natural number), a silicon oxide film (SiₓO_{y}, where each of ‘x’ and ‘y’ is a natural number), or a silicon nitride film (SiₓN_{y}, where each of ‘x’ and ‘y’ is a natural number).

The capping film 135 may be a material film formed at an outermost part of the air grid (ARD), and may be formed to cap or cover the air layer 133 and the support film 134. The capping film 135 may include an Ultra Low Temperature Oxide (ULTO) film such as a silicon oxide film (SiO₂). The capping film 135 may be formed to extend to a region in which the color filters of the unit pixels 112 and 122 are formed. Thus, the capping film 135 may extend to a lower region of each color filter.

The pixel grid pattern (PX_ARD) may be formed between the color filters of the effective pixels 112 in the effective pixel region 110 and between the color filters of the dummy pixels 122 in the dummy pixel region 120, and may thus prevent crosstalk between the color filters of the contiguous (or adjacent) pixels. For example, the pixel grid pattern (PX_ARD) may provide a lattice-shaped region in which the first light shielding patterns 102 and the second light shielding patterns 104 are formed in a lattice shape surrounding the effective pixels 112 and the dummy pixels 122.

The open grid pattern (OP_ARD) may provide a zigzag-shaped structure in which the first light shielding patterns 106 and the second light shielding patterns 108 are consecutively coupled in a zigzag pattern without crossing each other. For example, the first light shielding patterns 106 and the second light shielding patterns 108 are coupled to each other to form a contiguous structure. The open grid pattern (OP_ARD) may be formed in the dummy pixel region 120, and has an end portion coupled to the pixel grid pattern (PX_ARD). Thus, the air layer 133 of the pixel grid pattern (PX_ARD) and the air layer 133 of the open grid pattern (OP_ARD) are coupled to each other.

In some implementations, the open grid pattern (OP_ARD) may include an open region from which the capping film 135 is partially removed. The open region may denote a region in which the air layer 133 is not covered by the capping film 135. The open region may be formed in the other end of the open grid pattern (OP_ARD). Thus, one end of the open grid pattern (OP_ARD) may be integrally coupled to the pixel grid pattern (PX_ARD), and the other end of the open grid pattern (OP_ARD) may configure an open region from which the capping film 135 is removed.

When the air grid (ARD) is formed to include the capping film 135 to cap or cover the air layer 133, the capping film 135 may collapse as the air in the air layer 133 expands due to the thermal expansion.

In order to prevent the collapse of the capping film 135, the disclosed technology suggests to form an open grid pattern (OP_ARD) in the dummy pixel region 120 having an end portion in which the capping film 135 does not exist. As described above, when the open region from which the capping film 135 is removed is formed in the open grid pattern (OP_ARD), air can leak or move outside through the open region when the air in the air layer expands. Thus, it is possible to prevent that the collapse of the capping film 135.

FIG. 6 shows a comparison example in which the air grid is formed in a lattice shape and has an open area at one end portion of the air grid. In the open area, the capping film is removed. In FIG. 6, the open area is located very near the lattice shaped region of the air grid (ARD). Thus, foreign materials may easily flow into the air grid (ARD) through the open region in a subsequent process, which may cause the deterioration of the operational characteristics of the image sensing device in the subsequent process. In addition, if such foreign materials flow into the effective pixel region 110, the deterioration issue can become more serious.

In accordance with some implementations of the disclosed technology, the capping film 135 may be partially removed to form the open region, and the open grid pattern (OP_ARD) is formed. The open grid pattern (OP_ARD) has a line shape and the length of the open grid pattern (OP_ARD) can extend as long as possible such that foreign materials are prevented from flowing into the pixel grid pattern (PX_ARD) even when foreign materials flow through the open region. For example, the open grid pattern (OR_ARD) may be formed in a zigzag pattern as shown in FIG. 3.

Although FIG. 3 illustrates an exemplary structure in which the light shielding patterns 106 in the open grid patterns (OP_ARD) are provided across 8 unit pixels in the dummy pixel region 120, other implementations are also possible. Thus, the number of unit pixels corresponding to the length of the light shielding patterns 106 in the open grid patterns (OP_ARD) is not limited to 8.

FIGS. 7A to 7F are cross-sectional views illustrating a method for forming the structure shown in FIG. 4 based on some implementations of the disclosed technology.

Referring to FIG. 7A, the metal layer 131 may be formed over the semiconductor substrate 101 in which a photoelectric conversion element is formed.

For example, after a metal material (e.g., tungsten W) is formed over the semiconductor substrate 101, the metal material may be patterned using a mask pattern (not shown) defining the metal layer region of the air grid (ARD), resulting in formation of the metal layer 131. Prior to formation of the metal material, a barrier metal material may be formed and the metal material may also be formed over the barrier metal material.

Subsequently, the insulation layer 132 may be formed over the metal layer 131 so as to cover or cap the metal layer 131.

In some implementations, the insulation layer 132 may include a silicon nitride film (SiₓN_{y}, where each of ‘x’ and ‘y’ is a natural number) or a silicon oxide nitride film (SiₓO_{y}N_{z}, where each of ‘x’, ‘y’, and ‘z’ is a natural number).

Referring to FIG. 7B, a sacrificial film 136 may be formed over the insulation layer 132, and a support material layer 137 may be formed over the sacrificial film 136. In some implementations, the sacrificial film 136 may include a carbon-containing Spin On Carbon (SOC) film. The support material film 137 may include at least one of a silicon oxide nitride film (SiₓO_{y}N_{z}, where each of ‘x’, ‘y’, and ‘z’ is a natural number), a silicon oxide film (SiₓO_{y}, where each of ‘x’ and ‘y’ is a natural number), or a silicon nitride film (SiₓN_{y}, where each of ‘x’ and ‘y’ is a natural number).

Subsequently, a mask pattern 138 may be formed over the support material layer 137 to define the air layer region of the grid structure.

In some implementations, the mask pattern 138 may include a photoresist pattern.

Referring to FIG. 7C, the support material layer 137 may be etched using the mask pattern 138 as an etch mask, resulting in formation of the support film 134. The sacrificial film 136 may be etched using the support film 134 as a mask, resulting in formation of a sacrificial film pattern 136′.

Referring to FIG. 7D, the capping film 135 may be formed over the insulation layer 132, the sacrificial film pattern 136′, and the support film 134.

The capping film 138 may include an oxide film, for example, an Ultra Low Temperature Oxide (ULTO) film.

Referring to FIG. 7E, a mask pattern 139 may be formed over the capping film 135 to selectively open or expose only the end portion of the grid structure.

In some implementations, the mask pattern 139 may include a photoresist pattern.

Referring to FIG. 7F, the support film 134, the sacrificial film pattern 136′, the insulation layer 132, the metal layer 131, and the capping film 135 may be removed using the mask pattern 139 as an etch mask, such that the sacrificial film pattern 136′ may be exposed outside.

Subsequently, the plasma process may be carried out, such that the sacrificial film pattern 136′ may be removed and the air layer 133 may be formed at the position from which the sacrificial film pattern 136′ is removed. In some implementations, the plasma process may be carried out using gas (e.g., O₂, N₂, H₂, CO, CO₂, or CH₄) including at least one of oxygen, nitrogen, and hydrogen.

For example, if the O₂ plasma process is carried out, oxygen radicals (O*) may be combined with carbons of the sacrificial film pattern 136′, resulting in formation of CO or CO₂. The formed CO or CO₂ may be discharged outside through the position from which the capping film 135 is removed. By the above-mentioned process, the sacrificial film pattern 136′ may be removed, and the air layer 133 may be formed at the position from which the sacrificial film pattern 136′ is removed.

In some implementations, when the capping film 135 is formed as a thin film (e.g., a thickness of 300 Å or less), oxygen radicals (O*) may flow into the sacrificial film pattern 136′ through the capping film 135 during the plasma process, such that the oxygen radicals (O*) included in the sacrificial film pattern 136′ may be combined with carbons of the sacrificial film pattern 136′, resulting in formation of CO or CO₂. In addition, CO or CO₂ that have been formed may also be discharged outside through the capping film 135.

The support film 134 formed over the sacrificial film pattern 136′ may prevent the collapse of the capping film 135 due to removal of the sacrificial film pattern 136′.

Subsequently, the color filters 140 may be formed over the capping film 135.

FIG. 8 is a schematic diagram illustrating an air grid formed in the pixel region 100 shown in FIG. 1 based on some implementations of the disclosed technology. FIG. 9 is a horizontal cross-sectional view illustrating an example of the end portion of the open grid pattern shown in FIG. 8 based on some implementations of the disclosed technology.

Referring to FIGS. 8 and 9, the air grid (ARD) may include a pixel grid pattern (PX_ARD) and an open grid pattern (OP2_ARD).

The pixel grid pattern (PX_ARD) may include a plurality of first light shielding patterns 102 extending in a first direction, and a plurality of second light shielding patterns 104 extending in a second direction perpendicular to the first direction. The first light shielding patterns 102 and the second light shielding patterns 104 may be arranged to cross each other, such that the first light shielding patterns 102 and the second light shielding patterns 104 may be formed in a lattice shape.

The open grid pattern (OP2_ARD) may include a plurality of first light shielding patterns 106 extending in the first direction and a plurality of second light shielding patterns 108 extending in the second direction. The first light shielding patterns 106 and the second light shielding patterns 108 may be consecutively coupled in a zigzag pattern without crossing each other.

In some implementations, the end portion (which is denoted by the dotted circle in FIG. 8) of the open grid pattern (OP2_ARD) includes multiple second light shielding patterns 108 that are coupled to a light shielding pattern 106. The multiple second light shielding patterns 108 formed in the end portion (which is denoted by the dotted circle in FIG. 8) of the open grid pattern (OP2_ARD) may be arranged to be adjacent and parallel to each other. Having the multiple second light shielding patterns 108 arranged parallel in the end portion of the open grid pattern (OP2_ARD) is different from the structure as shown in FIG. 3 in which only one second light shielding pattern 108 is formed in the end portion of the open grid pattern (OP1_ARD). In some implementations, the plural second light shielding patterns 108 formed in the end portion of the open grid pattern (OP2_ARD) may be formed close to each other such that the capping films 135 formed between the second light shielding patterns 108 in the end portion of the open grid pattern (OP2_ARD) may have a thickness thinner than that in other regions. This is because a space between the two adjacent light shielding patterns 108 in the end portion of the open grid pattern (OP2_ARD) is very small and thus amount of the materials to be introduced to form the capping films 135 is reduced.

When a space between the adjacent light shielding patterns is small in size and the capping film is formed over the adjacent light shielding patterns, capping materials may not flow into the space as easily as the case in which an enough space is provided for the capping materials, such that a thin capping film may be formed at sidewalls of the second light shielding patterns 108 in the end portion of the open grid pattern (OP2_ARD).

The light shielding patterns 108 according to the present embodiment of the disclosed technology may be arranged parallel to each other in the end portion of the open grid pattern (OP2_ARD) while being arranged very close to each other. As a result, when the capping film 135 is formed in a manner as shown in FIG. 7D, a capping film 135 having a relatively thinner thickness may be formed at sidewalls between the light shielding patterns 108 in the end portion, as compared to the capping film 135 located on the external sidewall that is not between the two adjacent light shielding patterns.

In some implementations, if the O₂ plasma process is carried out, the sacrificial film pattern 136′ is removed, and the thermal annealing process is performed, a sidewall formed to a relatively thin thickness may collapse and be opened or exposed as shown in FIG. 9. Thus, a portion of the capping film 135 formed in the end portion of the open grid pattern (OP2_ARD) may be formed as thin as possible, such that the open region can be formed even without using the cutting process as shown in FIG. 7E.

Although FIG. 8 illustrates an exemplary structure in which the second light shielding patterns 108 extending in the second direction are arranged close and parallel to each other in the end portion of the open grid pattern (OP2_ARD), the first light shielding patterns 106 extending in the first direction may also be arranged close and parallel to each other as shown in FIG. 10.

FIG. 11 is a schematic diagram illustrating an air grid formed in the pixel region shown in FIG. 1 based on some implementations of the disclosed technology.

Referring to FIG. 11, the air grid (ARD) may include a pixel grid pattern (PX_ARD) and an open grid pattern (OP3_ARD).

The pixel grid pattern (PX_ARD) may include a plurality of first light shielding patterns 102 extending in a first direction and a plurality of second light shielding patterns 104 extending in a second direction perpendicular to the first direction. The first light shielding patterns 102 and the second light shielding patterns 104 may be formed in a lattice shape while simultaneously crossing each other.

The open grid pattern (OP3_ARD) may include a plurality of second light shielding patterns 109 extending in the second direction. The second light shielding patterns 109 may be arranged close and parallel to each other, and one end of the second light shielding patterns 109 may be coupled to the pixel grid pattern (PX_ARD).

The reason why the second light shielding patterns 109 are arranged close or adjacent to each other is identical to the reason that has been discussed above as to why the second light shielding patterns 108 are arranged close or adjacent to each other in the end portion of the above-mentioned open grid patterns (OP2_ARD). The open grid pattern (OP3_ARD) does not include the zigzag pattern unlike the above-mentioned open grid patterns OP1_ARD and OP2_ARD. Instead, the second light shielding patterns 109 may be formed as long as possible.

Although FIG. 11 illustrates an exemplary structure in which the open grid pattern (OP3_ARD) includes the second light shielding patterns 109 extending in the second direction, other implementations are also possible. For example, the open grid pattern (OP3_ARD) may include a plurality of first light shielding patterns extending in the first direction.

For example, when the dummy pixel region 120 is located at the left side or at the right side of the effective pixel region 110, the open grid pattern (OP3_ARD) may include the first light shielding patterns extending in the first direction.

In addition to examples in FIGS. 8, 10, and 11 with only one open grid pattern OP2_ARD or OP3_ARD, other implementations are also possible. For example, the open grid patterns OP2_ARD or OP3_ARD may be formed to surround the pixel grid pattern (PX_ARD) as illustrated in FIG. 2.

As is apparent from the above description, the image sensing device according to the embodiments of the disclosed technology can prevent collapse or deformation of the air grid by preventing expansion of the air grid.

Although a number of illustrative embodiments have been described, it should be understood that numerous other modifications and embodiments can be devised by those skilled in the art. Particularly, numerous variations and modifications are possible in the component parts and/or arrangements which are within the scope of the disclosure, the drawings and the accompanying claims. In addition to variations and modifications in the component parts and/or arrangements, alternative uses will also be apparent to those skilled in the art.

What is claimed is:

1. An image sensing device comprising:
a substrate;
an array of unit pixels each operable to receive light and to produce pixel signals representative of the received light, respectively;
a grid structure formed over the substrate and between adjacent unit pixels to prevent crosstalk between adjacent unit pixels,
wherein the grid structure includes:
a pixel grid region in which first light shielding patterns extending in a first direction and second light shielding patterns extending in a second direction perpendicular to the first direction are arranged to cross each other; and
an open grid region coupled to the pixel grid region and including first light shielding patterns extending in the first direction and second light shielding patterns extending in the second direction, the first light shielding patterns and the second light shielding patterns arranged not to cross each other;
wherein, in the pixel grid region, the first light shielding patterns and the second light shielding patterns include:
an air layer; and
a capping layer disposed over the air layer,
wherein the open grid region includes an open region in which at least one of the first light shielding patterns or the second light shielding patterns is configured to include an air layer without the capping layer disposed over the air layer.

2. The image sensing device according to claim 1, wherein the first light shielding patterns and the second light shielding patterns of the pixel grid region are arranged in a lattice shape.

3. The image sensing device according to claim 1, wherein the first light shielding patterns and the second light shielding patterns of the open grid region are arranged in a line shape.

4. The image sensing device according to claim 1, wherein the open grid region has a first end portion coupled to the pixel grid region and a second end portion opposite to the first end portion, and the open region is formed in the second end portion.

5. The image sensing device according to claim 1, wherein the first light shielding patterns and the second light shielding patterns of the open grid region are arranged in a zig-zag shape.

6. The image sensing device according to claim 1, wherein the open grid region has an end portion 1) in which at least two of the second light shielding patterns arranged in parallel are coupled to a first light shielding pattern or 2) in which at least two of the first light shielding patterns arranged in parallel are coupled to a second light shielding pattern.

7. The image sensing device according to claim 6, wherein the open region is formed at a sidewall between the at least two of the second light shielding patterns or between the at least two of the first light shielding patterns.

8. The image sensing device according to claim 1, wherein the open grid region is coupled to the pixel grid region through at least two of the first light shielding patterns arranged in parallel or at least two of the second light shielding patterns arranged in parallel.

9. The image sensing device according to claim 8, wherein the open region is formed at a sidewall between at least two of the first light shielding patterns or between the at least two of the second light shielding patterns.

10. The image sensing device according to claim 1, wherein, in each of the pixel grid region and the open grid region, the first light shielding patterns and the second light shielding patterns further include:
a metal layer formed below the air layer; and
an insulation layer formed to cap the metal layer.

11. The image sensing device according to claim 1, wherein the pixel grid region is formed in an effective pixel region in which effective pixels are provided and a dummy pixel region in which dummy pixels are provided, the effective pixels configured to detect light of a scene to produce pixel signals representing the detected scene including spatial information of the detected scene and the dummy pixels configured to detect light.

12. The image sensing device according to claim 11, wherein the open grid region is formed in the dummy pixel region and at a different location from the pixel grid region.

13. The image sensing device according to claim 1, further comprising one or more additional open grid region spaced apart from each other by a predetermined distance and arranged to surround the pixel grid region.

14. The image sensing device according to claim 1, wherein the capping layer includes an Ultra Low Temperature Oxide (ULTO) film.

15. The image sensing device according to claim 1, wherein, in the pixel grid region and the open grid region, the first light shielding patterns and the second light shielding patterns further include a support film disposed over the air layer.

16. An image sensing device comprising:
an active pixel region configured to include active pixels which detect light of a scene to produce pixel signals representing the detected scene including spatial information of the detected scene;
a dummy pixel region including dummy pixels located at different locations from locations of the active pixels of the active pixel region, each dummy pixel structured to detect light;
a first grid structure disposed in the active pixel region and a part of the dummy pixel region and including first light shielding patterns and second light shielding patterns that are arranged to cross each other and include an air layer and a capping layer disposed over the air layer; and
a second gird structure disposed in another part of the dummy pixel region and including first light shielding patterns and second light shielding patterns that are arranged not to cross each other,
wherein the second grid structure is configured to provide an open region in which at least one of the first light shielding patterns or the second light shielding patterns is configured to include an air layer without a capping layer disposed over the air layer.

17. The image sensing device of claim 16, wherein the first light shielding patterns and the second light shielding patterns of the first grid structure are arranged in a lattice shape.

18. The image sensing device according to claim 16, wherein the first light shielding patterns and the second light shielding patterns of the second grid structure are arranged in a line shape.

19. The image sensing device of claim 16, wherein the dummy pixel region is disposed to surround the active pixel region.

20. The image sensing device of claim 16, wherein the first grid structure and the second grid structure are coupled to each other at a first side of the second grid structure and the open region of the second grid structure is disposed at a second side opposite to the first side of the second grid structure.
